(19) United States
(12) Patent Application Publication
(10) Pub. No.: US 2018/0308790 A1
(43) Pub. Date: Oct. 25, 2018

(54) SEMICONDUCTOR MODULE

(71) Applicant: TOYOTA JIDOSHA KABUSHIKI KAISHA, Toyota-shi (JP)

(72) Inventor: Hiroaki YOSHIZAWA, Toyota-shi (JP)

(73) Assignee: TOYOTA JIDOSHA KABUSHIKI KAISHA, Toyota-shi (JP)

(21) Appl. No.: 15/955,116

(22) Filed: Apr. 17, 2018

(30) Foreign Application Priority Data
Apr. 25, 2017 (JP) 2017-086542

(51) Int. Cl. H01L 23/495; H01L 23/00

(52) U.S. Cl. CPC H01L 23/49513; H01L 23/49575; H01L 23/49568; H01L 23/49548; H01L 24/33; H01L 24/32; H01L 2924/3511; H01L 2224/33181; H01L 2224/3303; H01L 2224/32012; H01L 2224/32057; H01L 2224/32245; H01L 2924/181; H01L 23/49562; H01L 2924/13055; H01L 23/49537

(57) ABSTRACT

A semiconductor module may include a semiconductor chip; a first electrode body; and a second electrode body; wherein the semiconductor chip may include a semiconductor substrate; a first electrode layer that is in contact with a center portion of a first surface of the semiconductor substrate and is out of contact with a peripheral portion of the first surface; and a second electrode layer that is in contact with a center portion of a second surface of the semiconductor substrate and is out of contact with a peripheral portion of the second surface, the second surface being located on an opposite side with respect to the first surface, the first electrode body is connected to the first electrode layer via a first solder layer, and the second electrode body is connected to the second electrode layer via a second solder layer.

### TECHNICAL FIELD

The technology disclosed herein relates to a semiconductor module.

### BACKGROUND

Japanese Patent Application Publication No. 2003-007962 describes a semiconductor module including a semiconductor chip that is flip-chip mounted to a base substrate. In this semiconductor module, an adhesive that is used on a front surface side of the semiconductor chip and an adhesive that is used on a rear surface side of the semiconductor chip have same properties to suppress warpage of the semiconductor chip.

### SUMMARY

A semiconductor module including a semiconductor chip, a first electrode body connected to one of surfaces of the semiconductor chip, and a second electrode body connected to the other of the surfaces of the semiconductor chip is known. The semiconductor chip includes a semiconductor substrate, a first electrode layer that covers one of surfaces (a first surface) of the semiconductor substrate, and a second electrode layer that covers the other of the surfaces (a second surface) of the semiconductor substrate. The first electrode body is connected to the first electrode layer via a first solder layer. The second electrode body is connected to the second electrode layer via a second solder layer. In semiconductor chips of this type, the first electrode layer covers only a center portion of the first surface, and does not cover a peripheral portion of the first surface. In contrast, the second electrode layer covers a substantially entire region of the second surface. Thus, an area of a connection portion between the first electrode layer and the first solder layer is smaller than an area of a connection portion between the second electrode layer and the second solder layer. Therefore, heat generated in the semiconductor chip transfers more to the second electrode body than to the first electrode body. As a result, a temperature of the second electrode body is likely to become higher than that of the first electrode body. Since a surface of the second electrode body on a semiconductor chip side is restrained by the semiconductor chip via the second solder layer, when the second electrode body thermally expands, the second electrode body warps. At this occasion, the second electrode body warps such that its surface on an opposite side to the second solder layer protrudes. When the semiconductor chip repeatedly generates heat, the second electrode body repeatedly warps. Due to this, non-uniform stress is repeatedly applied to the second solder layer, and solder of the second solder layer moves therein due to a ratcheting phenomenon. As a result, a thickness of the second solder layer varies to become large at a center portion of the semiconductor chip and to become small at a peripheral portion of the semiconductor chip. When the thickness of the second solder layer varies as such, high stress is applied to the semiconductor chip, and reliability of the semiconductor chip is degraded.

In view of the above, the present disclosure provides a semiconductor module in which a ratcheting phenomenon is less likely to occur in a solder layer, and reliability of a semiconductor chip is less likely to be degraded.

A semiconductor module disclosed herein may comprise a semiconductor chip, a first electrode body, and a second electrode body. The semiconductor chip may comprise a semiconductor substrate, a first electrode layer that is in contact with a center portion of a first surface of the semiconductor substrate and is out of contact with a peripheral portion of the first surface, and a second electrode layer that is in contact with a center portion of a second surface of the semiconductor substrate and is out of contact with a peripheral portion of the second surface, the second surface being located on an opposite side with respect to the first surface. The first electrode body may be connected to the first electrode layer via a first solder layer. The second electrode body may be connected to the second electrode layer via a second solder layer.

In this semiconductor module, the first electrode layer is out of contact with the peripheral portion of the first surface, and the second electrode layer is out of contact with the peripheral portion of the second surface as well. Due to this, a difference between an area of a connection portion between the first electrode layer and the first solder layer and an area of a connection portion between the second electrode layer and the second solder layer is smaller than in conventional semiconductor modules. Thus, heat generated by the semiconductor chip transfers therefrom more uniformly to the first electrode body and the second electrode body than in the conventional semiconductor modules. Therefore, a temperature difference between the first electrode body and the second electrode body when a temperature of the semiconductor chip becomes high is smaller than in the conventional semiconductor modules, and hence the second electrode body is less likely to warp. For this reason, a ratcheting phenomenon is less likely to occur in the second solder layer, and hence a thickness of the second solder layer is less likely to vary. Due to this, in this semiconductor module, reliability of the semiconductor chip is less likely to be degraded.

### BRIEF DESCRIPTION OF DRAWINGS

FIG. 1 is a plan view of a semiconductor module according to an embodiment;

FIG. 2 is a cross-sectional view of the semiconductor module according to the embodiment, along a line II-II in FIG. 1;

FIG. 3 is a cross-sectional view of a semiconductor module according to a comparative example; and

FIG. 4 is a cross-sectional view of a semiconductor module according to a variant.

### DETAILED DESCRIPTION

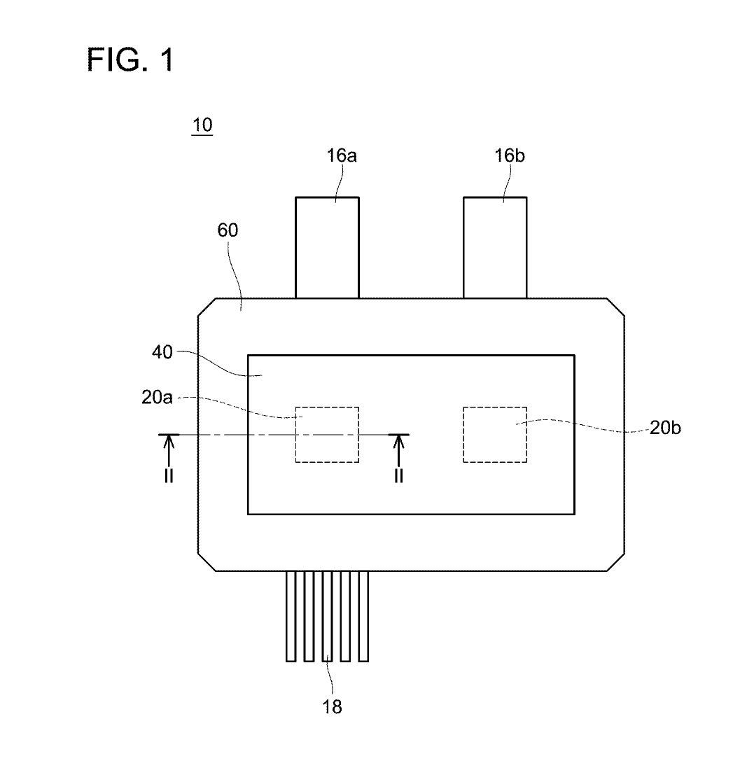

A semiconductor module 10 according to an embodiment shown in FIG. 1 includes a structure in which semiconductor chips 20a and 20b are embedded in an insulating resin layer 60. Further, main terminals 16a and 16b, and a plurality of signal terminals 18 protrude from an inside of the insulating resin layer 60 to an outside thereof. The main terminals 16a and 16b and the signal terminals 18 are connected to the semiconductor chip 20a or the semiconductor chip 20b in the insulating resin layer 60. Further, a lead frame 40 is exposed on an upper surface of the insulating resin layer 60. The lead frame 40 is connected to the semiconductor chip 20a and the semiconductor chip 20b.

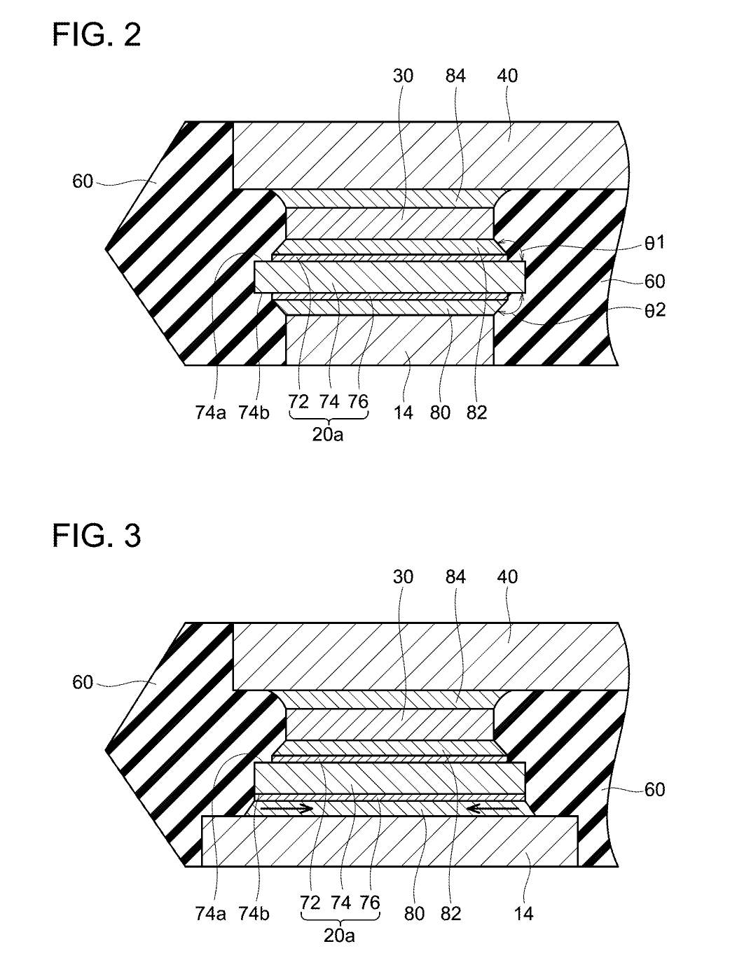

As shown in FIG. 2, the semiconductor chip 20a includes a semiconductor substrate 74, an upper electrode layer 72, and a lower electrode layer 76. The semiconductor substrate 74 is constituted of silicon. An Insulated gate bipolar transistor (IGBT) is formed in the semiconductor substrate 74. The upper electrode layer 72 is in contact with an upper surface 74a of the semiconductor substrate 74. The upper electrode layer 72 covers a center portion of the upper surface 74a, and does not cover a peripheral portion of the upper surface 74a. Although not shown, the peripheral portion of the upper surface 74a is provided with a plurality of signal electrodes. Each of the signal electrodes is connected to corresponding one of the signal terminals 18 (refer to FIG. 1) via a wire (not shown). The lower electrode layer 76 is in contact with a lower surface 74b of the semiconductor substrate 74. The lower electrode layer 76 covers a center portion of the lower surface 74b, and does not cover a peripheral portion of the lower surface 74b. The lower surface 74b is not provided with any electrode other than the lower electrode layer 76. In a transparent view of the semiconductor chip 20a along its thickness direction, a contour of the upper electrode layer 72 and a contour of the lower electrode layer 76 substantially match each other. Thus, an area of a region where the upper electrode layer 72 is in contact with the semiconductor substrate 74 is substantially equal to an area of a region where the lower electrode layer 76 is in contact with the semiconductor substrate 74. More specifically, the area of the region where the upper electrode layer 72 is in contact with the semiconductor substrate 74 is 0.95 to 1.05 times the area of the region where the lower electrode layer 76 is in contact with the semiconductor substrate 74.

A metal block 30 is disposed above the semiconductor chip 20a. The metal block 30 is disposed above the upper electrode layer 72. The metal block 30 is constituted mainly of copper. A lower surface of the metal block 30 is connected to the upper electrode layer 72 via a solder layer 82. The solder layer 82 is connected to an entirety of the lower surface of the metal block 30 and to an entirety of an upper surface of the upper electrode layer 72. An area of the lower surface of the metal block 30 is smaller than an area of the upper surface of the upper electrode layer 72. Thus, the solder layer 82 includes a shape in which a width of the solder layer 82 narrows from the upper electrode layer 72 toward the metal block 30. Therefore, an angle θ1 between a lateral surface of the solder layer 82 and the peripheral portion of the upper surface 74a of the semiconductor substrate 74 is obtuse. Since the angle θ1 is obtuse, when the insulating resin layer 60 is formed by injection molding, molten resin easily spreads over a boundary portion between the lateral surface of the solder layer 82 and the peripheral portion of the upper surface 74a (that is, a portion at which the angle θ1 is formed). Due to this, formation of a void and the like at this portion is suppressed.

The lead frame 40 is disposed above the metal block 30. The lead frame 40 is constituted mainly of copper. A lower surface of the lead frame 40 is connected to an upper surface of the metal block 30 via a solder layer 84.

A lead frame 14 is disposed below the semiconductor chip 20a. The lead frame 14 is constituted mainly of copper. The lead frame 14 is disposed below the lower electrode layer 76. Although not shown, the lead frame 14 is connected to the main terminal 16a (refer to FIG. 1). An upper surface of the lead frame 14 is connected to the lower electrode layer 76 via a solder layer 80. The solder layer 80 is connected to an entirety of the upper surface of the lead frame 14 and an entirety of a lower surface of the lower electrode layer 76. An area of the upper surface of the lead frame 14 is smaller than an area of the lower surface of the lower electrode layer 76. Thus, the solder layer 80 includes a shape in which a width of the solder layer 80 narrows from the lower electrode layer 76 toward the lead frame 14. Therefore, an angle θ2 between a lateral surface of the solder layer 80 and the peripheral portion of the lower surface 74b of the semiconductor substrate 74 is obtuse. Since the angle θ2 is obtuse, when the insulating resin layer 60 is formed by injection molding, molten resin easily spreads over a boundary portion between the lateral surface of the solder layer 80 and the peripheral portion of the bottom surface 74b (that is, a portion at which the angle θ2 is formed). Due to this, formation of a void and the like at this portion is suppressed. An area of a connection portion between the solder layer 82 and the upper electrode layer 72 is substantially equal to an area of a connection portion between the solder layer 80 and the lower electrode layer 76. More specifically, the area of the connection portion between the solder layer 82 and the upper electrode layer 72 is 0.95 to 1.05 times the area of the connection portion between the solder layer 80 and the lower electrode layer 76.

The insulating resin layer 60 covers the lead frame 40, the solder layer 84, the metal block 30, the solder layer 82, the semiconductor chip 20a, the solder layer 80, and the lead frame 14. However, an upper surface of the lead frame 40 and a lower surface of the lead frame 14 are exposed from the insulating resin layer 60.

When a current flows in the semiconductor chip 20a, the semiconductor chip 20a generates heat. While the semiconductor module 10 is used, the current repeatedly flows through the semiconductor chip 20a, and the semiconductor chip 20a repeatedly generates heat. Hereinbelow, thermal stress that is generated during an operation of the semiconductor module 10 will be described by comparison with a semiconductor module according to a comparative example shown in FIG. 3. It should be noted that, in FIG. 3, portions of the semiconductor module according to the comparative example that have the same functions as those of the portions of the semiconductor module 10 according to the embodiment are denoted with the same reference signs as those in FIG. 2. In the semiconductor module according to the comparative example shown in FIG. 3, the lower electrode layer 76 covers an entirety of the lower surface 74b of the semiconductor substrate 74. Further, the upper surface of the lead frame 14 is larger than the lower surface of the lower electrode layer 76. Thus, the solder layer 80 includes a shape in which the width of the solder layer 80 widens from the lower electrode layer 76 toward the lead frame 14. Except for these differences, a structure of the semiconductor module according to the comparative example shown in FIG. 3 is the same as the structure of the semiconductor module 10 according to the embodiment shown in FIG. 2.

In the semiconductor module according to the comparative example shown in FIG. 3, when the semiconductor chip 20a generates heat, the heat transfers from the semiconductor chip 20a to the lead frame 40 and the lead frame 14. That is, the heat transfers from the semiconductor chip 20a to the lead frame 40 via the solder layer 82, the metal block 30, and the solder layer 84, and the heat also transfers from the semiconductor chip 20a to the lead frame 14 via the solder layer 80. In the semiconductor module according to the comparative example, since the area of the connection portion between the solder layer 80 and the lower electrode layer 76 is larger than the area of the connection portion between the solder layer 82 and the upper electrode layer 72, the heat transfers more to the lead frame 14 than to the lead frame 40. Thus, a temperature of the lead frame 14 becomes higher than that of the lead frame 40. Here, the upper surface of the lead frame 14 is connected, via the solder layer 80, to the semiconductor substrate 74 which is hard. Due to this, a portion of the lead frame 14 on its upper surface side is restrained by the semiconductor substrate 74, and is less likely to thermally expand. In contrast, a portion of the lead frame 14 on its lower surface side is likely to thermally expand. Thus, as the temperature of the lead frame 14 increases, an amount of the thermal expansion in the portion on the lower surface side becomes larger than an amount of the thermal expansion in the portion on the upper surface side. As a result, the lead frame 14 warps to protrude downward. When the semiconductor chip 20a repeatedly generates heat, the lead frame 14 repeatedly warps. In accordance therewith, stress is repeatedly applied to the solder layer 80. Thus, due to a ratcheting phenomenon, solder constituting the solder layer 80 moves toward a center of the solder layer 80 as indicated by arrows in FIG. 3. As a result, the solder layer 80 becomes thicker at its center portion than at its peripheral portion. Due to this, stress is applied to the semiconductor chip 20a in a manner that makes it warp, and reliability of the semiconductor chip 20a is degraded.

In contrast, in the semiconductor module 10 according to the embodiment shown in FIG. 2, the area of the connection portion between the solder layer 82 and the upper electrode layer 72 is substantially equal to the area of the connection portion between the solder layer 80 and the lower electrode layer 76. Thus, heat generated by the semiconductor chip 20a transfers more uniformly to the lead frame 40 and the lead frame 14 than in the semiconductor module according to the comparative example. Therefore, the temperature of the lead frame 14 is less likely to increase in the semiconductor module 10 according to the embodiment than in the semiconductor module according to the comparative example. For this reason, the lead frame 14 is less likely to warp. In particular, since a temperature difference between the lead frame 40 and the lead frame 14 is small, a balance between stress to be generated on a lead frame 40 side and stress to be generated on a lead frame 14 side is easily maintained, and thus the lead frame 14 is suppressed from warping. As a result, stress to be applied to the solder layer 80 is reduced, and the ratcheting phenomenon is less likely to occur in the solder layer 80. Due to this, stress to be applied to the semiconductor chip 20a can be reduced, and the degradation of the reliability of the semiconductor chip 20a can be suppressed.

As described hereinabove, in the semiconductor module 10 according to the embodiment, the area of the connection portion between the solder layer 82 and the upper electrode layer 72 is substantially equal to (more specifically, 0.95 to 1.05 times) the area of the connection portion between the solder layer 80 and the lower electrode layer 76, and thus stress to be applied to the semiconductor chip 20a can be reduced as compared to in conventional semiconductor modules. Due to this, the degradation of the reliability of the semiconductor chip 20a can be suppressed.

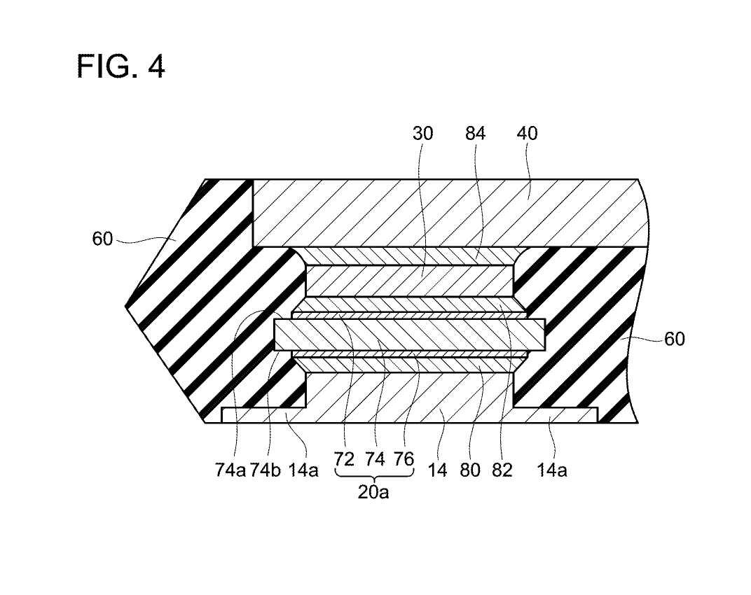

It should be noted that, as shown in FIG. 4, the lead frame 14 may include a part 14a (such as a conductive path) that protrudes outward from the solder layer 80 at a position that is out of contact with the solder layer 80. With this configuration as well, stress to be applied to the semiconductor chip 20a can be reduced as in the semiconductor module 10 according to the embodiment.

Now, relationships between the constituent elements of the embodiment described hereinabove and constituent elements in the claims are described. The metal block 30 of the embodiment is an example of “first electrode body” in the claims. The lead frame 14 of the embodiment is an example of “second electrode body” in the claims. The upper electrode layer 72 of the embodiment is an example of “first electrode layer” in the claims. The lower electrode layer 76 of the embodiment is an example of “second electrode layer” in the claims. The solder layer 82 of the embodiment is an example of “first solder layer” in the claims. The solder layer 80 of the embodiment is an example of “second solder layer” in the claims.

Some of the features characteristic to the disclosure herein will be listed below. It should be noted that the respective technical elements are independent of one another, and are useful solely or in combinations.

In an example of semiconductor module disclosed herein, an area of a connection portion between the first electrode layer and the first solder layer may be 0.95 to 1.05 times an area of a connection portion between the second electrode layer and the second solder layer.

In an example of semiconductor module disclosed herein, the first solder layer may include a shape in which a width of the first solder layer narrows from the first electrode layer toward the first electrode body. Further, the second solder layer may include a shape in which a width of the second solder layer narrows from the second electrode layer toward the second electrode body. The semiconductor module may further comprise an insulating resin layer covering the semiconductor chip, the first solder layer, and the second solder layer.

With this configuration, angles formed at boundary portions between surfaces of the semiconductor chip in ranges not covered by the respective electrode layers and lateral surfaces of the respective solder layers are each obtuse. Thus, at a time of resin molding, molten resin easily flows into these boundary portions. Therefore, a void and the like are less likely to be formed at these boundary portions.

While specific examples of the present invention have been described above in detail, these examples are merely illustrative and place no limitation on the scope of the patent claims. The technology described in the patent claims also encompasses various changes and modifications to the specific examples described above. The technical elements explained in the present description or drawings provide technical utility either independently or through various combinations. The present invention is not limited to the combinations described at the time the claims are filed. Further, the purpose of the examples illustrated by the present description or drawings is to satisfy multiple objectives simultaneously, and satisfying any one of those objectives gives technical utility to the present invention.

What is claimed is:

1. A semiconductor module, comprising:
a semiconductor chip;
a first electrode body; and
a second electrode body;
wherein
the semiconductor chip comprises:
a semiconductor substrate;
a first electrode layer that is in contact with a center portion of a first surface of the semiconductor substrate and is out of contact with a peripheral portion of the first surface; and
a second electrode layer that is in contact with a center portion of a second surface of the semiconductor substrate and is out of contact with a peripheral portion of the second surface, the second surface being located on an opposite side with respect to the first surface,
the first electrode body is connected to the first electrode layer via a first solder layer, and
the second electrode body is connected to the second electrode layer via a second solder layer.

2. The semiconductor module of claim 1, wherein an area of a connection portion between the first electrode layer and the first solder layer is 0.95 to 1.05 times an area of a connection portion between the second electrode layer and the second solder layer.

3. The semiconductor module of claim 1, wherein
the first solder layer includes a shape in which a width of the first solder layer narrows from the first electrode layer toward the first electrode body,
the second solder layer includes a shape in which a width of the second solder layer narrows from the second electrode layer toward the second electrode body, and
the semiconductor module further comprises an insulating resin layer covering the semiconductor chip, the first solder layer, and the second solder layer.
